(19) United States
(12) Patent Application Publication
(10) Pub. No.: US 2026/0217579 A1
(43) Pub. Date: Jul. 30, 2026

(54) OZONE WATER GENERATION DEVICE AND GENERATION METHOD

(71) Applicants: MEIDENSHA CORPORATION, Shinagawa-ku, Tokyo (JP); MEIDEN NANOPROCESS INNOVATIONS, INC., Shinagawa-ku, Tokyo (JP); EcoDesign, Inc., Hiki-gun, Saitama (JP)

(72) Inventors: Naoki KATO, Kiyosu-shi, Aichi (JP); Toshinori MIURA, Nagoya-shi, Aichi (JP); Yasuo KARASAWA, Numazu-shi, Shizuoka (JP); Masaaki NAGAKURA, Hiki-gun, Ogawa-machi (JP)

(73) Assignees: MEIDENSHA CORPORATION, Shinagawa-ku, Tokyo (JP); MEIDEN NANOPROCESS INNOVATIONS, INC., Shinagawa-ku, Tokyo (JP); EcoDesign, Inc., Hiki-gun, Saitama (JP)

(21) Appl. No.: 19/141,928

(22) PCT Filed: Dec. 18, 2023
(86) PCT No.: PCT/JP2023/045261

§ 371 Date: Jun. 20, 2025

(30) Foreign Application Priority Data
Dec. 23, 2022 (JP) 2022-206639

(51) Int. Cl. C02F 1/78; B01F 21/20; B01F 23/237; B01F 35/221

(52) U.S. Cl. CPC C02F 1/78; B01F 21/20; B01F 23/237613; B01F 35/2215; B01F 35/2213; C02F 2201/78

(57) ABSTRACT

In a state in which a solvent capable of dissolving ozone gas is circulated in a circulation line, the solvent temperature is appropriately controlled, and the solvent is caused to flow to a gas-liquid mixer to which the ozone gas is supplied at an arbitrary supply pressure, thereby mixing and dissolving the ozone gas in the solvent. The gas-liquid mixer includes a solvent flow path through which the solvent flows, and an ozone gas introduction path connected to the solvent flow path and introducing the ozone gas supplied to the gas-liquid mixer into the solvent flow path. Then, the solvent temperature is controlled such that the solvent vapor pressure is less than the ozone gas supply pressure, and the ozone gas supplied to the gas-liquid mixing has an ozone concentration of 50 volume % or greater and an ozone partial pressure of 30 kPa (abs) or less.

### TECHNICAL FIELD

The present invention relates to a technology that can contribute to an ozone water generation device and generation method.

### BACKGROUND TECHNOLOGY

Ozone water which is obtained by dissolving ozone into a solvent (for example, pure water or other raw material water) has a strong oxidizing power and has been used for sterilization, for example, in water supply systems and food products. This use of ozone water is valued as an environmental-friendly method because ozone is easily decomposed into oxygen in the end, and it does not leave any residual chemicals behind.

In recent years, there has been attempted to use ozone water in washing processes used to manufacture various industrial components, such as precision electronic components (for example, semiconductor devices and display components such as FPD), and there has been considered to increase the concentration and ensure a stable industrial supply of ozone water.

A patent document 1 discloses to increase the concentration of ozone water by first cooling (concentrating) ozone gas to obtain ozone water, then re-vaporizing the ozone water, collecting the ozone gas (concentrated ozone gas) with a cooling collector which has been obtained by the re-vaporizing, and further dissolving the collected material (liquid or solid ozone) in water to obtain ozone water.

A patent document 2 discloses a configuration in which a washing liquid is obtained by simultaneously dissolving ozone gas and carbon dioxide gas in raw material water (for example, raw material water at 25° C. or less (preferably, raw material water at 5° C. to 20° C.)), and then the washing liquid is brought into contact with a resist film (organic film) on a substrate while being heated to 45° C. or higher, thereby maintaining a high concentration of ozone in the washing liquid and making it easier to remove the resist film.

In a patent document 3, there is disclosed that ozone water is generated by mixing raw material water with ozone gas of an ozone gas generator (in the patent document 3, a device that uses oxygen gas as a raw material) using a gas-liquid mixer, and by providing an orifice between the ozone gas generator and the gas-liquid mixer, it is possible to suppress the ozone gas generator side from becoming a negative pressure state (that is, a state below atmospheric pressure (approximately 101.33 kPa)), thereby improving the efficiency of ozone gas dissolution.

A patent document 4 discloses a configuration that includes an ozone water circulation line that circulates ozone water and an ozone gas contact mechanism (permeable membrane made of fluororesin) that causes the raw material water to come in contact with the exhausted ozone gas exhausted from the ozone water circulation line, thereby increasing the concentration of the ozone water by the effective use of the exhausted ozone gas.

In a patent document 5, there is disclosed that ozone water is generated by mixing raw material water with ozone gas of an ozone gas generator (in the patent document 5, a device that uses oxygen gas as a raw material) using a gas-liquid mixer, and the ozone water (in the patent document 5, the ozone water in the tank indicated by the symbol 34) that has been reduced in concentration too much by the raw material water is cased to pass through the gas-liquid mixer to increase the concentration of the ozone water.

In the patent document 1, there is disclosed that CF₄ gas is applied as an inhibitor to suppress a self-decomposition reaction in the case where the rapid self-decomposition reaction of ozone might occur due to external factors (for example, electrical sparks, triggers such as contamination that induces decomposition).

According to the configurations shown in the patent documents 1 to 5, although there is possibility that ozone water with a certain ozone concentration (for example, approximately 100 ppm) can be generated, it is thought that ozone water with a further higher concentration (for example, 200 ppm or higher in the washing process of semiconductor devices) is required in the washing process that requires relatively high oxidation power.

### PRIOR ART DOCUMENT(S)

### Patent Document(s)

Patent Document 1: Japanese Patent Application Publication No. H11-262782
Patent Document 2: Japanese Patent No. 4296393
Patent Document 3: Japanese Patent No. 4746515
Patent Document 4: Japanese Patent No. 5213601
Patent Document 5: Japanese Patent No. 7041466

### Non-Patent Document(S)

Non-Patent Document 1: TAIYO NIPPON SANSO Technical Report No. 28 (2009) “Measurement Equipment for Explosion Limits”

### SUMMARY OF THE INVENTION

For example, as shown in the patent documents 3 and 5, in a configuration using a gas-liquid mixer, when the supply pressure of ozone gas supplied to the gas-liquid mixer is increased (to a pressure higher than atmospheric pressure), the ozone gas might be more easily dissolved in a solvent, and high-concentration ozone water could be obtained.

However, as mentioned above, if the supply pressure of ozone gas is simply increased, as shown in the non-patent document 1, a rapid self-decomposition reaction of ozone occurs easily, making it difficult to maintain practical safety, and there is therefore a risk that a stable industrial supply cannot be achieved.

The present invention has been made into consideration of such a technical problem, and an object of the present invention is to provide a technology that can contribute to stably supplying high-concentration ozone water easily.

An ozone water generation device and method according to the present invention are capable of contributing to solve the above problem, and the ozone water generation device, in one aspect thereof, is provided with: a circulation line that circulates a solvent that is capable of dissolving ozone gas; a control unit configured to control a temperature of the solvent; and a gas-liquid mixer through which the solvent flows and to which the ozone gas is supplied at an arbitrary supply pressure, in a circulation state in which the solvent circulates.

In addition, the gas-liquid mixer includes a solvent flow path through which the solvent flows, and an ozone gas introduction path that is connected to the solvent flow path and introduces the ozone gas supplied to the gas-liquid mixer into the solvent flow path.

Then, the control unit controls the temperature of the solvent such that a vapor pressure of the solvent is less than the supply pressure of the ozone gas, and the ozone gas has an ozone concentration of 50 volume % or greater and an ozone partial pressure of 30 kPa (abs) or less.

An ozone water generation method, in one aspect thereof, includes: a circulation operation of circulating, by a circulation line, a solvent that is capable of dissolving ozone gas; a temperature control operation of controlling a temperature of the solvent, in a state in which the solvent is circulated by the circulation operation; and a gas-liquid mixing operation of allowing the solvent to flow into a gas-liquid mixer to which the ozone gas is supplied at an arbitrary supply pressure, in the state in which the solvent is circulated by the circulation operation.

In addition, the gas-liquid mixer includes a solvent flow path through which the solvent flows, and an ozone gas introduction path that is connected to the solvent flow path and introduces the ozone gas supplied to the gas-liquid mixer into the solvent flow path.

Then, the temperature control operation is performed to control the temperature of the solvent such that a vapor pressure of the solvent is less than the supply pressure of the ozone gas, and the ozone gas supplied by the gas-liquid mixing operation has an ozone concentration of 50 volume % or greater and an ozone partial pressure of 30 kPa (abs) or less.

As the above, according to the present invention, it is possible to contribute to stably supplying high-concentration ozone water easily.

### BRIEF DESCRIPTION OF THE DRAWINGS

FIG. 1 is a schematic block diagram to explain the configuration of a generation device A of ozone water according to an embodiment.

FIG. 2 (a) is a chart with a saturation vapor pressure curve of water, and FIG. 2 (b) is a vapor pressure table.

FIG. 3 is a change characteristic diagram with a lapse of time which is obtained by observing the flow rate of ozone gas (O₃ flow rate) supplied by the gas-liquid mixing operation in the verification example, the discharge amount of ozone water (O₃ water extraction amount) extracted in the discharge operation, and the ozone concentration (O₃ water concentration).

### MODE FOR IMPLEMENTING THE INVENTION

An ozone water generation device and generation method of an embodiment in the present invention is completely different from a configuration that simply uses a gas-liquid mixer (hereinafter, simply referred to as a “conventional configuration”), as shown, for example, in the patent documents 3 and 5.

That is, in the present embodiment, in a state in which a solvent (for example, raw material water, pure water or ultrapure water) that is capable of dissolving ozone gas is circulated through a circulation line, the temperature of the solvent (hereinafter simply referred to as a “solvent temperature”) is appropriately controlled, and the solvent is caused to flow into a gas-liquid mixer to which the ozone gas is supplied at an arbitrary supply pressure, thereby mixing and dissolving the ozone gas in the solvent.

In addition, the gas-liquid mixer is provided with a solvent flow path through which a solvent flows, and an ozone gas introduction path that is connected to the solvent flow path and introduces ozone gas supplied to the gas-liquid mixer into the solvent flow path. Then, the solvent temperature is controlled such that the vapor pressure of the solvent is lower than the supply pressure, and the ozone gas supplied to the gas-liquid mixer has an ozone concentration of 50 volume % or greater and an ozone partial pressure of 30 kPa (abs) or less.

According to the present embodiment, since high-concentration ozone gas in which the ozone partial pressure has been sufficiently reduced can be applied, it is possible to sufficiently suppress the occurrence of the rapid self-decomposition reaction in the ozone gas, thereby maintaining practical safety. In addition, since the vapor pressure of the solvent flowing through the gas-liquid mixer is controlled to be lower than the supply pressure (that is, the total pressure) of the ozone gas supplied to the gas-liquid mixer, the ozone gas is easily dissolved in the solvent. Therefore, it is possible to contribute to making it easier to stably supply high-concentration ozone water.

The generation device and generation method of the present embodiment is sufficient to have a configuration in which ozone gas (ozone gas with an ozone concentration of 50 volume % or greater and an ozone partial pressure of 30 kPa (abs) or less) supplied to a gas-liquid mixer at an arbitrary supply pressure can be dissolved into the solvent while appropriately controlling the solvent temperature as described above. That is, it is possible to apply the technical knowledge of various fields (for example, the fields of ozone gas and ozone water generation) as appropriate, and the design can be changed while appropriately referring to prior art documents as necessary, and, as one example thereof, the following embodiment can be cited. In the following embodiment, detailed explanations are omitted as appropriate, for example, by using the same symbols for the same content.

### Reference

For example, in the case of the conventional ozone gas generator (ozonizer) that has been used in the conventional configuration, the ozone gas that is generated has a low concentration (for example, an ozone concentration of 20 volume % or less), and it contains a large amount of gas (hereafter is referred to as a “non-ozone component”) due to components other than ozone (for example, oxygen). Even if such low-concentration ozone gas is used, it is difficult to generate high-concentration ozone water, and it is dissolved with a large amount of non-ozone components.

In addition, ozone water, which is generated by dissolving low-concentration ozone gas as mentioned above in a solvent under high pressure to increase its concentration, contains, in addition to the ozone component, non-ozone components in a supersaturated state. When this ozone water is released into the atmosphere, bubbles caused by the non-ozone components are formed and disperse into the air easily, and the ozone component also disperses more easily, as a result of which the ozone water cannot be maintained in a high concentration state.

In recent years, it has become possible to generate high-concentration ozone gas (for example, ozone concentration of 50 volume % or greater) by concentrating ozone gas generated by, for example, an ozonizer, using, for example, an adsorption concentration type (a method that uses surface adsorption of silica gel and the like) or a cooling concentration type.

For example, the cooling concentration type ozone gas generator (product name: Pure Ozone Generator) made by MEIDENSHA CORPORATION can generate extremely high-concentration ozone gas with an ozone concentration of nearly 100 volume % (ozone concentration of 90 volume % or greater), and it has also been certified to international safety standards (SEMI-S2) to ensure practical safety.

However, it is necessary to maintain a reduced pressure state such that a rapid self-decomposition reaction does not occur even with the ozone gas that has been concentrated as mentioned above, and it is difficult to apply it to the conventional configuration (namely, a configuration that prevents the ozone gas generator side from becoming a negative pressure state).

On the other hand, in the present embodiment, since ozone gas is applied in a pressure reduced state (ozone partial pressure of 30 kPa (abs) or less), it is possible to safely use the extremely high-concentration ozone gas that has been concentrated as mentioned above, and thereby a desired high-concentration ozone water can be generated.

Specifically, in the case where ozone gas has an ozone concentration of 90 volume % or greater and an oxygen concentration of less than 10 volume %, by reducing the total pressure of the ozone gas to 30 kPa (abs) or less (namely, reducing the ozone partial pressure to 30 kPa (abs) or less), the ozone gas can be safely maintained.

In addition, in the case where ozone gas has an ozone concentration of 50 volume % or greater and an oxygen concentration of less than 50 volume %, by reducing the total pressure of ozone gas to 60 kPa (abs) or less (namely, reducing the ozone partial pressure to 30 kPa (abs) or less), the ozone gas can be safely maintained.

### Embodiment

### <Example of Configuration of Ozone Water Generation Device A>

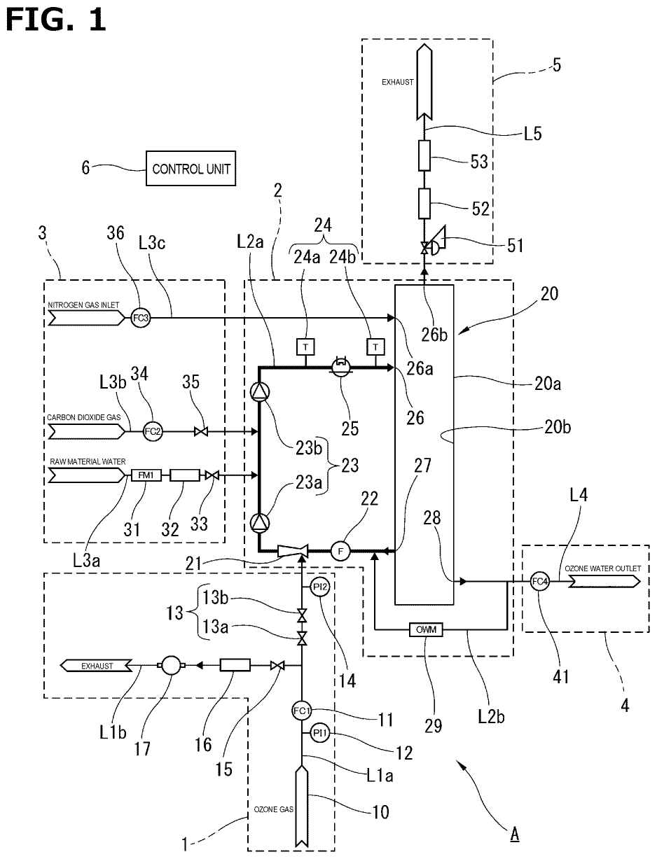

FIG. 1 is a schematic block diagram to explain the configuration of an ozone water generation device A according to an embodiment. This device A mainly includes an ozone gas supply part 1 that can supply ozone gas with an ozone concentration of 50 volume % or greater under a pressure reduced state, a circulation part 2 that introduces a solvent that can dissolve the ozone gas of the ozone gas supply part 1 and circulates it (circulates it in the clockwise direction as shown in FIG. 1), a solvent supply part 3 that supplies the solvent and gas to the circulation part 2, and a control unit 6 that controls the ozone gas supply part 1, circulation part 2, solvent supply part 3 and the like by appropriately acquiring information indicating the status of the ozone gas supply part 1, circulation part 2, solvent supply part 3 and the like (for example, the measurement value of a temperature measuring resistor 24 in a circulation line L2a described below (solvent temperature); hereinafter simply referred to as “status information”).

Furthermore, in the case of the device A shown in FIG. 1, it is configured to have a discharge part 4 that discharges the solvent in the circulation part 2 to the outer peripheral side of the circulation part 2 (releases the solvent in which ozone gas is dissolved, namely, ozone water), and an exhaust part 5 that exhausts, from the circulation part 2, the gas-phase gas separated from the solvent, and each of which is controlled by the control unit 6 by appropriately acquiring the status information.

### <Example of Configuration of Ozone Gas Supply Part 1>

The ozone gas supply part 1 shown in FIG. 1 mainly includes an ozone gas generator 10, an ozone gas supply line L1a that supplies the ozone gas generated by the ozone gas generator 10 to the circulation part 2 (via the gas-liquid mixer 21 described below), and an ozone gas exhaust line L1b connected to the ozone gas supply line L1a and used to exhaust the ozone gas in the ozone gas supply line L1a (to, for example, adjust the gas pressure of the ozone gas supply line L1a).

In the ozone gas supply part 1, the ozone gas generator 10 can be any type that can generate ozone gas with an ozone concentration of 50 volume % or greater and supply it in the pressure reduced state, and various types can be applied. As an example, a configuration that concentrates ozone gas generated by, for example, an ozonizer using an adsorption concentration type or a cooling concentration type can be cited.

In addition, the adsorption concentration type is one that uses surface adsorption phenomenon, for example, with silica gel to concentrate the ozone gas, and if impurities such as NOx or heavy metals are mixed in the ozone gas to be concentrated, there is possibility that these impurities are also concentrated during a concentration process. For this reason, it is preferable to remove these impurities in advance if they are mixed therein.

On the other hand, the cooling concentration type is one that vaporizes liquid ozone obtained by cooling the ozone gas to be concentrated. In addition, because the vapor pressure of the ozone gas and impurities differ from each other (for example, by a level of several digits), the ozone gas concentrated by the cooling concentration type (ozone gas after vaporization) contains, in principle, almost no impurities. Therefore, it can be said that the cooling concentration type is preferably applied when there is possibility that impurities are mixed in the ozone gas to be concentrated.

Next, the ozone gas supply line La is provided with a gas flow rate controller 11 to control the flow rate of the ozone gas flowing through the ozone gas supply line L1a. In addition, on the upstream of the gas flow rate controller 11 (on the side of the ozone gas generator 10), a pressure gauge 12 is provided which measures the gas pressure of the ozone gas flowing on the upstream side (namely, the supply pressure of the ozone gas supplied to the gas-liquid mixer 21 described below).

Furthermore, on the downstream side of the gas flow rate controller 11, an opening/closing valve (for example, a check valve, and in FIG. 1, there are two opening/closing valves) 13 is provided which can switch the flow of the ozone gas in the ozone gas supply line L1a (to supply or reverse flow of the ozone gas). Furthermore, on the downstream side of the opening/closing valve 13, a pressure gauge 14 is provided which measures the gas pressure on the downstream side. This pressure gauge 14 can measure the gas pressure corresponding to the suction pressure when suctioning the ozone gas by the gas-liquid mixer 21 described below, and it is possible to evaluate the suction pressure.

Next, in the ozone gas exhaust line L1b, an opening/closing valve 15 is provided which is connected in communication between the gas flow rate controller 11 and the opening/closing valve 13 in the ozone gas supply line L1a, and which can switch the flow (exhaust) of the ozone gas from the ozone gas supply line L1a. In addition, the ozone gas exhaust line L1b is provided, on the downstream side of the opening/closing valve 15, with an ozone decomposer (ozone killer) 16 that decomposes the ozone gas flowing through the ozone gas exhaust line L1b to a safe state, and a vacuum pump 17 that sucks in and exhausts the decomposed ozone gas.

### <Example of Configuration of Circulation Part 2>

The circulation part 2 shown in FIG. 1 is mainly provided with a circulation line L2a that can introduce and circulate the solvent of the solvent supply part 3, a circulation tank 20 that is connected to the circulation line L2a and is capable of introducing a certain amount of the solvent and storing it, a reflux line L2b that refluxes the solvent discharged from the circulation tank 20 to the circulation line L2a, and a gas-liquid mixer 21 that mixes the solvent and ozone gas.

In the circulation line L2a of the circulation part 2, the ozone gas supplied from the ozone gas supply part 1 to the gas-liquid mixer 21 is introduced into the circulation line L2a via the gas-liquid mixer 21 and is dissolved in the solvent. In the circulation part 2 shown in FIG. 1, both the circulation line L2a and the gas-liquid mixer 21 are illustrated as being connected and integrated, but are not limited to this configuration, and they may be configured separately from each other.

Although an ejector, aspirator, jet pump or the like can be applied as the gas-liquid mixer 21, the gas-liquid mixer 21 is not limited to them, and various types can be applied. In other words, it is sufficient for the gas-liquid mixer 21 to have a solvent flow path (not shown in the drawings) through which the solvent flows, and an ozone gas introduction path (not shown in the drawings) which is connected to the solvent flow path and introduces the ozone gas supplied to the gas-liquid mixer 21 into the solvent flow path.

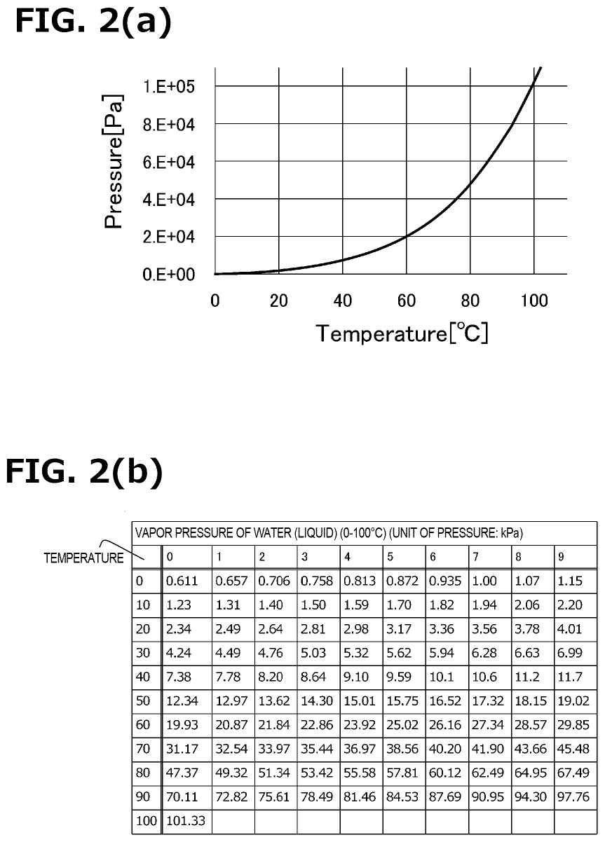

According to the gas-liquid mixer 21 having the solvent flow path and the ozone gas introduction path as described above, suction pressure is generated in the ozone gas introduction path according to the flow rate (flow speed) of the solvent flowing through the solvent flow path based on Bernoulli's theorem. In addition, vapors are generated in the ozone gas introduction path according to the saturated vapor pressure of the solvent. For example, when the solvent is raw material water, it has the characteristics shown in the saturation vapor pressure curve and the vapor pressure table for water in FIG. 2.

According to the characteristics of the solvent shown in FIG. 2 and the supply pressure of ozone gas with respect to the gas-liquid mixer 21, it is possible to derive a range of a solvent temperature (hereinafter referred to as a “suctioning range”) in which the vapor pressure in the ozone gas introduction path of the gas-liquid mixer 21 is lower than the supply pressure. This suctioning range is preferably set to be a relatively low temperature range, at least higher than the freezing point of the solvent (temperature at which the solvent does not freeze), taking into account the general solubility characteristics of gases with respect to solvents (solubility tends to increase as the temperature of the solvent decreases).

Then, by appropriately controlling the solvent temperature to be within the range of the suctioning temperature (as in the temperature control operation described below) by the control unit 6, it is possible to set the vapor pressure in the ozone gas introduction path of the gas-liquid mixer 21 to be lower than the supply pressure of the ozone gas supplied to the gas-liquid mixer 21. Specifically, it is preferably set such that the measurement value of the pressure gauge 14 is lower than the measurement value of the pressure gauge 12. With this, the ozone gas in the ozone gas supply line L1a is easily introduced into the ozone gas introduction path of the gas-liquid mixer 21, and it is possible to dissolve the ozone gas by mixing it with the solvent.

On the upstream side of the gas-liquid mixer 21, a circulation flow meter 22 is provided which measures the circulation flow rate of the solvent circulating in the circulation line L2a. On the downstream side of the gas-liquid mixer 21, a circulation pump (two circulation pumps in FIG. 1) 23 is provided which circulates the solvent. As shown in FIG. 1, by providing two circulation pumps 23a and 23b, it is possible to, for example, normally operate one of the circulation pumps 23a and 23b, and when the primary pressure of the one falls too low, the other of the circulation pumps 23a and 23b can function as an auxiliary pump. However, the other one may be omitted as appropriate depending on the situation of the circulation part 2 (circulation conditions and the like).

In addition, on the downstream side of the circulation pump 23, a temperature measuring resistor (two temperature measuring resistors in FIG. 1) 24 for measuring the temperature of the solvent and a temperature controller (for example, a cooler) 25 for adjusting the temperature of the solvent are provided. By controlling these temperature measuring resistor 24 and temperature controller 25 as appropriate by the control unit 6, the solvent temperature can be set to the suctioning range.

Next, the circulating tank 20 is provided with a cylindrical peripheral wall 20a having a bottom and capable of storing a certain amount of the solvent, and the inner wall surface of the peripheral wall 20a is formed in a shape having a cylindrical side wall inner peripheral surface 20b having an axis extending in the vertical direction.

On the upper side of the peripheral wall 20a, an introduction port 26 communicating with the downstream side of a temperature measuring resistor 24b in the circulation line 2La (namely, the downstream side of the gas-liquid mixer 21), an introduction port 26a communicating with the pressure adjustment line L3c described below, and an exhaust port 26b communicating with the gas exhaust line L5 described below are provided.

On the lower side of the peripheral wall 20a, a lead-out port 27 communicating with the upstream side of the circulation flow meter 22 in the circulation line L2a (namely, the upstream side of the gas-liquid mixer 21), and a discharge port 28 communicating with the solvent discharge line L4 described below are provided.

Although the shape of the introduction port 26 is not particularly limited, for example, as shown in FIG. 1, the introduction port 26 is provided at the position of the side wall inner peripheral surface 20b, and is formed in a shape opening on one side in the circumference direction of the side wall inner peripheral surface 20b. According to the introduction port 26 having the opening in the side wall inner peripheral surface 20b, the solvent introduced into the circulation tank 20 through the introduction port 26 is stored in such a way that it moves on the lower side in the vertical direction while swirling along the side wall inner peripheral surface 20b (for example, it moves while generating a swirling flow as indicated by the symbol S in the Japanese Patent No. 6954645).

When the solvent moves while swirling along the side wall inner peripheral surface 20b as described above, the liquid phase component with a high density of the solvent is more likely to move along the side wall inner peripheral surface 20b by centrifugal force, while the gas phase component with a low density is more likely to be condensed toward the axis of the side wall inner peripheral surface 20b. That is, the solvent that swirls as described above makes it easier for efficient gas-liquid separation to occur, and it is possible to move the gas phase component (gas phase gas) that is generated by the gas-liquid separation to the upper side of the circulation tank 20, and to store the liquid phase component on the lower side of the circulation tank 20.

Next, the reflux line L2b is connected to communicate between the upstream side of the solvent discharge line L4 described below and the upstream side of the circulation flow meter 22 in the circulation line L2a, so as to allow the solvent on the upstream side of the solvent discharge line L4 (namely, the solvent discharged from the discharge port 28) to be refluxed into the circulation line L2a. In addition, the reflux line L2b is provided with an ozone concentration measuring instrument 29 that can measure the ozone concentration of the solvent which is refluxed by the reflux line L2b. By the ozone concentration measuring instrument 29 provided in the reflux line L2b, rather than simply measuring the ozone concentration of the solvent in the circulation line L2a, it is possible to measure the same ozone concentration as that of the solvent actually discharged from the circulation tank 20 (namely, the ozone water as a target).

### <Example of Configuration of Solvent Supply Part 3>

The solvent supply part 3 shown in FIG. 1 is provided with a solvent supply line L3a that can supply a solvent such as raw material water to the circulation line L2a, a concentration adjustment line L3b that can supply a concentration adjustment gas (for example, carbon dioxide gas) that stabilizes the ozone concentration of the solvent in the circulation line L2a, and a pressure adjustment line L3c that can supply a pressure adjustment gas (for example, an inert gas such as N₂, Ar and He) for adjusting the pressure in the circulation tank 20.

In the solvent supply part 3, the solvent supply line L3a is connected in communication between the circulation pumps 23a and 23b in the circulation line L2a, and is provided with a solvent flow rate controller 31 that can control the flow rate of the solvent flowing through the solvent supply line L3a. In addition, on the downstream side of the solvent flow rate controller 31, it is provided with a water purification portion (for example, a water purification device) 32 that can increase the purity of the solvent flowing through the solvent supply line L3a, and an opening/closing valve 33 that can switch the flow of the solvent in the solvent supply line L3a.

Next, the concentration adjustment line L3b is connected in communication between the circulation pumps 23a and 23b in the circulation line L2a, and is provided with a gas flow rate controller 34 that can control the flow rate of the concentration adjustment gas flowing through the concentration adjustment line L3b. In addition, on the downstream side of the gas flow rate controller 34, it is provided with an opening/closing valve 35 that can switch the flow of the concentration adjustment gas in the concentration adjustment line L3b.

Next, the pressure adjustment line L3c is connected to and communicates with the introduction port 26a of the circulating tank 20, and is provided with a gas flow rate controller 36 that can control the flow rate of the pressure adjustment gas flowing through the pressure adjustment line L3c.

### <Example of Configuration of Discharge Part 4>

The discharge part 4 shown in FIG. 1 is provided with a solvent discharge line L4 that discharges the solvent in the circulation tank 20 to the outer peripheral side of the circulation tank 20. This solvent discharge line L4 is connected to and communicates with the discharge port 28 of the circulation tank 20, and is provided with a discharge flow rate controller 41 that can control the discharge flow rate of the solvent discharged through the solvent discharge line L4.

### <Example of Configuration of Exhaust Part 5>

The exhaust part 5 shown in FIG. 1 is provided with a gas exhaust line L5 that exhausts gas (for example, gas phase component generated from the solvent by gas-liquid separation) in the circulation tank 20 to the outer peripheral side of the circulation tank 20. This gas exhaust line L5 is connected to and communicates with the exhaust port 26b of the circulation tank 20, and is provided with an opening/closing valve (such as a back pressure adjustment valve) 51 that can switch the flow (exhaust) of the gas inside the circulation tank 20 while maintaining a constant pressure inside the circulation tank 20. In addition, the gas exhaust line L5 is provided, on the downstream side of the opening/closing valve 51, with an ozone concentration measuring instrument 52 that can measure the ozone concentration of the ozone gas flowing through the gas exhaust line L5, and an ozone decomposer 53 that decomposes the ozone gas flowing through the gas exhaust line L5 to a safe state.

### <Example of Configuration of Control Unit 6>

The control unit 6 shown in FIG. 1 is sufficient to be configured to acquire the status information of the ozone gas supply part 1, circulation part 2, solvent supply part 3, discharge part 4, and exhaust part 5 as needed and control them such that a target ozone water can be obtained, and various configurations can be applied.

For example, a configuration can be applied in which the control unit 6 and an equipment (for example, a measuring instrument, adjustment instrument, controller, opening/closing valve, circulation pump, temperature measuring resistor) which are provided in each line (ozone gas supply line L1a, ozone gas exhaust line L1b, circulation line L2a, circulation line L2b, solvent supply line L3a, concentration adjustment line L3b, pressure adjustment line L3c, solvent discharge line L4 and gas exhaust line L5) are connected as appropriate via signal lines and the like which are not shown in the drawings.

According to such a configuration, it is possible to acquire status information for the equipment by operating each of the lines as appropriate, and based on the acquired status information, it is possible to output control commands to the equipment and control it.

### <Example of Ozone Water Generation Method by Device A>

In the device A shown above, it is possible to generate a desired ozone water by performing a circulation operation, temperature control operation, gas-liquid mixing operation, discharge operation, and exhaust operation shown below as appropriate.

First, in the circulation operation, the solvent is supplied to the circulation line L2a by opening the opening/closing valve 33 of the solvent supply line L3a, to fill the circulation line L2a with the solvent. The amount of the solvent circulated that fills the circulation line L2a is set appropriately, for example, such that the liquid level of the solvent in the circulation tank 20 is positioned between the introduction port 26 and lead-out port 27.

Then, by, for example, operating the circulation pump 23 of the circulation line L2a, the circulation line L2a is made into a state in which the solvent circulates at a predetermined circulation flow rate (hereinafter simply referred to as a “circulation state”). During this circulation state, the concentration adjustment line L3b and the pressure adjustment line L3c are also operated, as needed, to stabilize the ozone concentration of the circulating solvent in the circulation line L2a to adjust the pressure inside the circulation tank 20.

Next, in the temperature control operation, the suctioning range is determined in advance based on the supply pressure of the ozone gas in ozone gas supply operation in the later stage and the characteristics shown in the saturated vapor pressure curve and vapor pressure table in FIG. 2. Then, in the circulation state, the temperature of the solvent in the circulating line L2a is adjusted using a temperature controller 25 such that the solvent temperature is within the suctioning range, while measuring the solvent temperature in the circulating line L2a using the temperature measuring resistor 24. For example, when the target is ozone water with an ozone concentration of 300 ppm or greater, the suctioning range is set to be higher than the freezing point of the solvent and 15° C. or less.

Next, in the gas-liquid mixing operation, ozone gas is supplied to the gas-liquid mixer 21 by, for example, opening the opening/closing valve 13 of the ozone gas supply line L1a, in the circulation state. Here, since the circulating solvent temperature is within the suctioning range by the temperature control operation in the previous stage, the supply pressure of the ozone gas to the gas-liquid mixer 21 is greater than the vapor pressure of the ozone gas introduction path of the gas-liquid mixer 21.

As a result, the ozone gas supplied to the gas-liquid mixer 21 is introduced into the solvent flow path via the ozone gas introduction path in the gas-liquid mixer 21, and becomes a state in which it can be dissolved by being mixed with the solvent in the solvent flow path. Then, by the ozone gas being dissolved in the solvent, the solvent becomes to have a desired ozone concentration.

In addition, when the measurement value of the pressure gauge 14 becomes larger than the measurement value of the pressure gauge 12 in a state of supplying ozone gas by the gas-liquid mixing operation, the opening/closing valve 13 is switched and controlled to the open state. With this, it is possible to suppress the occurrence of backflow of ozone gas in the ozone gas supply line L1a.

Next, in the discharge operation, the solvent in the circulation tank 20 is discharged (namely, the target ozone water is obtained) by appropriately controlling the discharge flow rate controller 41 of the solvent discharge line L4, in the circulation state. In addition, by appropriately supplying the solvent from the solvent supply line L3a to the circulation line L2a, the discharge flow rate of the solvent is controlled so as not become larger than the circulating flow rate of the solvent in the circulation line L2a.

With this, the solvent can be discharged while maintaining a certain amount of the solvent stored in the circulating tank 20. That is, it is possible to continuously extract ozone water with a desired ozone concentration during the discharge operation.

Next, in the exhaust operation, by, for example, opening the opening/closing valve 51 of the gas exhaust line L5, the gas (for example, the gas phase component separated from the circulating solvent) that exists in the circulating tank 20 is exhausted to the outer peripheral side of the circulating tank 20.

### <Verification>

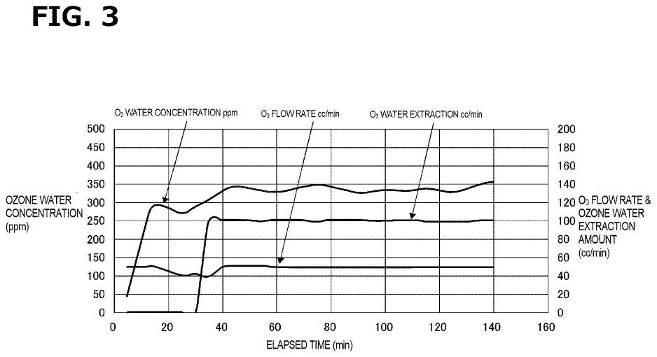

Ozone water was generated by appropriately performing the circulation operation, temperature control operation, gas-liquid mixing operation, discharge operation, exhaust operation and the like as shown above by using the device A having the configuration shown in FIG. 1. Then, the amount of impurities in the metal and non-metal elements (Li, Na, Mg, Al, K, Ca, Ti, V, Cr, Mn, Fe, Co, Ni, Cu, Zn, Cd, Sn, Ba, Pb, Si) contained in the ozone water was observed at the ppb level using inductively coupled plasma mass spectrometry (ICP-MS), and the results shown in Table 1 below were obtained. In addition, when the change characteristics with the lapse of time were observed for the flow rate of ozone gas supplied by the gas-liquid mixing operation (O₃ flow rate in FIG. 3), the discharge amount of ozone water extracted by the discharge of the discharge operation (O₃ water extraction amount in FIG. 3), and the ozone concentration (O₃ water concentration in FIG. 3), the results shown in FIG. 3 were obtained.

In addition, a pure ozone generator made by MEIDENSHA CORPORATION was applied to the ozone gas generator 10 of the device A, and ozone gas with an ozone concentration of 90 volume % or greater was supplied to the gas-liquid mixer 21 under a pressure reduced state in which the total pressure is 30 kPa (abs) or less in the gas-liquid mixing operation. In addition, the suctioning range was set between 10° C. to 15° C.

TABLE 1
Unit: ppb

| | Element to be measured | | | | |
|---|---|---|---|---|---|
| | Na | Cr | Fe | Cu | Al |
| Analysis | less | less | less | less | less |
| value | than 0.1 | than 0.5 | than 0.5 | than 0.5 | than 0.5 |

According to the results in Table 1, it can be seen that the ozone water generated by the device A contains almost no impurities of metallic or non-metallic elements, and that the amount of impurities of Na, Cr, Fe, Cu, and Al is kept below the limit of quantification.

According to the results of FIG. 3, it can be seen that the device A is able to continuously release ozone water with a high concentration of 300 ppm or greater while maintaining a certain amount of the solvent stored in the circulation tank 20. It can also be seen that the ozone concentration of the ozone water is kept almost unchanged. That is, it was confirmed that a stable supply of high-concentration ozone water was possible.

### <Example of Application for Ozone Water Generated by Device A>

For example, in the case of Si semiconductors, when the general RCA washing operation is performed, there is possibility that Si dangling bonds expose on the surface of the Si substrate. Normally, the dangling bonds are hydrogen-terminated in the hydrofluoric acid treatment operation in the later stage and the like, and the adhesion of contaminants to the dangling bonds is suppressed.

However, since the lifetime of the hydrogen termination is short (for example, only a few hours), if the hydrogen-terminated state is to be maintained for a long period of time, it is necessary to form a thin oxide film on the Si substrate surface such that the dangling bonds are not exposed. That is, it can be thought that after the RCA washing, an extremely thin Si oxide film is formed on the Si substrate surface by applying ozone water having a high concentration. However, if the ozone water applied contains impurities of metallic or non-metallic elements, these impurities are incorporated into the Si oxide film, and a target Si semiconductor product cannot be obtained.

Therefore, when forming the Si oxide film as described above, by applying the ozone water generated by the device A, it is possible to suppress the incorporation of impurities into the Si oxide film, and a target Si semiconductor product can be obtained easier.

As the above, in the present invention, although the details of only the described specific examples have been explained, it is obvious to those skilled in the art that various changes and the like are possible within the scope of the technical concept of the present invention, and it is natural that such changes and the like belong to the scope of the claims.

1. An ozone water generation device comprising:
a circulation line that circulates a solvent that is capable of dissolving ozone gas;
a control unit configured to control a temperature of the solvent; and
a gas-liquid mixer through which the solvent flows and to which the ozone gas is supplied at an arbitrary supply pressure, in a circulation state in which the solvent circulates,
wherein the gas-liquid mixer includes:
a solvent flow path through which the solvent flows; and
an ozone gas introduction path that is connected to the solvent flow path and introduces the ozone gas supplied to the gas-liquid mixer into the solvent flow path,
wherein the control unit controls the temperature of the solvent such that a vapor pressure of the solvent is less than the supply pressure of the ozone gas, and
wherein the ozone gas has an ozone concentration of 50 volume % or greater and an ozone partial pressure of 30 kPa (abs) or less.

2. The ozone water generation device according to claim 1,
wherein the control unit controls the temperature of the solvent to be higher than a freezing point of the solvent and 15° C. or less.

3. The ozone water generation device according to claim 1,
wherein the ozone gas has an ozone concentration of 90 volume % or greater.

4. The ozone water generation device according to claim 1,
wherein the ozone gas is supplied to the gas-liquid mixer via an opening/closing valve, and
wherein when the vapor pressure of the solvent is greater than the supply pressure of the ozone gas, the control unit closes the opening/closing valve.

5. The ozone water generation device according to claim 1,
wherein the gas-liquid mixer is connected to the circulation line.

6. The ozone water generation device according to claim 1, further comprising a discharge part that discharges the solvent,
wherein the control unit controls a discharge flow rate of the solvent that is discharged from the discharge part to be smaller than a circulation flow rate of the solvent in the circulation state.

7. The ozone water generation device according to claim 1,
wherein a circulation tank that introduces the solvent and stores it is connected to the circulation line.

8. The ozone water generation device according to claim 7,
wherein an exhaust part that exhausts a gas-phase gas separated from the solvent introduced into the circulation tank is provided on an upper side in a vertical direction of the circulating tank.

9. The ozone water generation device according to claim 7,
wherein an inner wall surface of the circulation tank has a cylindrical side wall inner peripheral surface having an axis extending in a vertical direction,
wherein the side wall inner peripheral surface is provided with an introduction port that communicates with a downstream side of the gas-liquid mixer in the circulation line, and introduces the solvent into the circulation tank from the downstream side,
wherein on a lower side in the vertical direction than the introduction port in the inner wall surface, a lead-out port that communicates with an upstream side of the gas-liquid mixer in the circulation line and leads the solvent introduced into the circulation tank to the upstream side, and a discharge port that communicates with an outer peripheral side of the circulation part and discharges the solvent introduced into the circulation tank are provided, and
wherein the introduction port is formed in a shape opening toward one side in a circumference direction in the side wall inner peripheral surface.

10. The ozone water generation device according to claim 7,
wherein the control unit controls a pressure inside the circulation tank by supplying an inert gas into the circulation tank.

11. An ozone water generation method comprising:
a circulation operation of circulating, by a circulation line, a solvent that is capable of dissolving ozone gas;
a temperature control operation of controlling a temperature of the solvent, in a state in which the solvent is circulated by the circulation operation; and
a gas-liquid mixing operation of allowing the solvent to flow into a gas-liquid mixer to which the ozone gas is supplied at an arbitrary supply pressure, in the state in which the solvent is circulated by the circulation operation,
wherein the gas-liquid mixer includes:
a solvent flow path through which the solvent flows; and
an ozone gas introduction path that is connected to the solvent flow path and introduces the ozone gas supplied to the gas-liquid mixer into the solvent flow path,
wherein the temperature control operation is performed to control the temperature of the solvent such that a vapor pressure of the solvent is less than the supply pressure of the ozone gas, and
wherein the ozone gas supplied by the gas-liquid mixing operation has an ozone concentration of 50 volume % or greater and an ozone partial pressure of 30 kPa (abs) or less.

12. The ozone water generation method according to claim 11,
wherein, in the temperature control operation, the temperature of the solvent is controlled to be higher than a freezing point of the solvent and 15° C. or less.

13. The ozone water generation method according to claim 11,
wherein the ozone gas has an ozone concentration of 90 volume % or greater.

14. The ozone water generation method according to claim 11,
wherein, in the gas-liquid mixing operation, the ozone gas is supplied to the gas-liquid mixer via an opening/closing valve, and when the vapor pressure of the solvent is greater than the supply pressure of the ozone gas, the opening/closing valve is closed.

15. The ozone water generation method according to claim 11, further comprising a discharge operation of discharging the solvent,
wherein, in the discharge operation, a discharge flow rate of the solvent that is discharged by the discharge operation is controlled to be smaller than a circulation flow rate of the solvent that is circulated by the circulation operation.

16. The ozone water generation method according to claim 11, wherein the gas-liquid mixer is connected to the circulation line.

17. The ozone water generation method according to claim 11, wherein a circulation tank that introduces the solvent and stores it is connected to the circulation line.

18. The ozone water generation method according to claim 17, further comprising an exhaust operation of exhausting, from an upper side in a vertical direction of the circulation tank, a gas-phase gas separated from the solvent introduced into the circulation tank.

19. The ozone water generation method according to claim 17,
wherein an inner wall surface of the circulation tank has a cylindrical side wall inner peripheral surface having an axis extending in a vertical direction,
wherein the side wall inner peripheral surface is provided with an introduction port that communicates with a downstream side of the gas-liquid mixer in the circulation line, and introduces the solvent into the circulation tank from the downstream side,
wherein on a lower side in the vertical direction than the introduction port in the inner wall surface, a lead-out port that communicates with an upstream side of the gas-liquid mixer in the circulation line and leads the solvent introduced into the circulation tank to the upstream side, and a discharge port that communicates with an outer peripheral side of the circulation part and discharges the solvent introduced into the circulation tank are provided, and
wherein the introduction port is formed in a shape opening toward one side in a circumference direction in the side wall inner peripheral surface.

20. The ozone water generation method according to claim 17, further comprising a pressure control operation of controlling a pressure inside the circulation tank by supplying an inert gas into the circulation tank.
